(19) United States
(12) Patent Application Publication
(10) Pub. No.: US 2013/0167472 A1
(43) Pub. Date: Jul. 4, 2013

(54) Photovoltaic Roofing Elements And Photovoltaic Roofing Systems

(71) Applicants: Robert L. Jenkins, Honeybrook, PA (US); Christopher C. Fisher, Philadelphia, PA (US)

(72) Inventors: Robert L. Jenkins, Honeybrook, PA (US); Christopher C. Fisher, Philadelphia, PA (US)

(21) Appl. No.: 13/732,773

(22) Filed: Jan. 2, 2013

Related U.S. Application Data
(60) Provisional application No. 61/582,509, filed on Jan. 3, 2012.

(51) Int. Cl. H01L 31/042

(52) U.S. Cl. CPC H01L 31/0422
USPC 52/745.06; 136/244; 136/252

(57) ABSTRACT

The present invention relates generally to the photovoltaic generation of electrical energy. The present invention relates more particularly to photovoltaic arrays for use in photovoltaically generating electrical energy. Aspects of the present invention provide a variety of rigid photovoltaic roofing elements and systems using them that include adjustable leveling elements. The adjustable leveling elements can allow the rigid photovoltaic roofing elements to be supported on substantially nonplanar roofs, and can allow the rigid photovoltaic roofing elements to be leveled with respect to adjacent photovoltaic roofing elements or an overall roof plane.

### BACKGROUND OF THE INVENTION

This application claims the benefit of priority under 35 U.S.C. §119(e) of U.S. Provisional Patent Application Ser. No. 61/582,509, filed Jan. 3, 2012, which is hereby incorporated herein by reference in its entirety.

### BACKGROUND OF THE INVENTION

1. Field of the Invention

The present invention relates generally to the photovoltaic generation of electrical energy. The present invention relates more particularly to photovoltaic roofing products for use in photovoltaically generating electrical energy.

2. Technical Background

The search for alternative sources of energy has been motivated by at least two factors. First, fossil fuels have become increasingly expensive due to increasing scarcity and unrest in areas rich in petroleum deposits. Second, there exists overwhelming concern about the effects of the combustion of fossil fuels on the environment due to factors such as air pollution (from NOₓ, hydrocarbons and ozone) and global warming (from CO₂). In recent years, research and development attention has focused on harvesting energy from natural environmental sources such as wind, flowing water, and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as system performance has improved. They can be used, for example, to provide at least a significant fraction of the electrical energy needed for a building's overall function; or they can be used to power one or more particular devices, such as exterior lighting systems and well pumps. Research and development attention has turned toward the development of photovoltaic products that are adapted to be installed on a roof. While stand-alone photovoltaic modules have been in use for some time, they tend to be heavy and bulky, and aesthetically unfavorable when installed on a roof. Roofing products having photovoltaic cells integrated with roofing products such as shingles, shakes or tiles, or roofing panels have been proposed. Examples of such proposals have been disclosed in U.S. Patent Application Publications nos. 2006/0042683A1, 2008/0149163A1, 2010/0313499A1 and 2010/0313501A1, and in U.S. Pat. No. 4,040,867, each of which is hereby incorporated by reference herein in its entirety. A plurality of such photovoltaic roofing elements (i.e., including photovoltaic media integrated with a roofing product) can be installed together on a roof, and electrically interconnected to form a photovoltaic roofing system that provides both environmental protection and photovoltaic power generation.

In some systems, such as those described in U.S. Patent Application Publications nos. 2009/0000222 and in U.S. patent application Ser. No. 13/326,094, photovoltaic media are disposed on rigid roofing substrates to form rigid photovoltaic roofing elements, for example, in the form of tiles or panels. However, the present inventors have determined that such photovoltaic roofing elements can be problematic to install on roof surfaces that are substantially non-planar. For example, non-planar roof surfaces can result from a distorted or misapplied rafter, building settling, or roof deck board distortion. Application of a rigid photovoltaic roofing element over an uneven roof surface can result in a number of disadvantages. For example, if a portion of the rigid photovoltaic roofing element is not adequately supported by the roof surface, it can be subject to breakage when walked upon. Further, if adjacent rigid photovoltaic roofing elements are not substantially coplanar, significant gaps can be opened between them, allowing the potential for water infiltration. Moreover, disposition of an array rigid photovoltaic roofing elements on an uneven surface can result in a substantially irregular appearance of the array. These potential problems identified by the present inventors demonstrate a need for new photovoltaic roofing elements and systems that address one or more of these deficiencies.

### SUMMARY OF THE INVENTION

One aspect of the invention is a rigid photovoltaic roofing element including a rigid roofing substrate having a top face and a bottom face; and a photovoltaic element disposed on the top face of the rigid roofing substrate, wherein the rigid roofing substrate includes one or more adjustable leveling elements extending from the bottom face thereof.

Another aspect of the invention is a photovoltaic roofing system including a plurality of rigid photovoltaic roofing elements as described herein, arranged in an array and disposed on a roof

Another aspect of the invention is a kit for the installation of a photovoltaic roofing system. The kit includes a rigid photovoltaic roofing element including a rigid roofing substrate having a top face and a bottom face, and a photovoltaic element disposed on the top face of the rigid roofing substrate; and one or more adjustable leveling elements configured to interface with the bottom face of the rigid roofing substrate.

Another aspect of the invention is a method for the installation of a photovoltaic roofing system. The method includes disposing on a roof a rigid photovoltaic roofing element including a rigid roofing substrate having a top face and a bottom face, and a photovoltaic element disposed on the top face of the rigid roofing substrate; and disposing one or more adjustable leveling elements extending from the bottom face of the rigid roofing substrate of the rigid photovoltaic roofing element to the roof; and then adjusting one or more of the adjustable leveling elements.

The invention will be further described with reference to embodiments depicted in the appended figures. It will be appreciated that elements in the figures are illustrated for simplicity and clarity and have not necessarily been drawn to scale. For example, the dimensions of some of the elements in the figures may be exaggerated relative to other elements to help to improve understanding of embodiments of the invention.

### BRIEF DESCRIPTION OF THE DRAWINGS

The accompanying drawings are not necessarily to scale, and sizes of various elements can be distorted for clarity.

FIG. 1 is a schematic cross-sectional view of a rigid photovoltaic roofing element according to one embodiment of the invention;

FIGS. 2, 3 and 4 are partial schematic cross-sectional views of adjustable leveling elements according to certain embodiments of the invention;

FIG. 5 is a partial schematic cross-sectional view of an adjustable leveling element according to one embodiment of the invention;

FIG. 6 is a schematic cross-sectional view of an adjustable leveling element according to another embodiment of the invention;

FIG. 7 is a schematic cross-sectional view of an adjustable leveling element according to another embodiment of the invention;

FIG. 8 is a partial schematic cross-sectional view of adjustable leveling elements according to various embodiments of the invention;

FIG. 9 is a schematic top perspective view of a rigid roofing substrate according to one embodiment of the invention;

FIG. 10 is a schematic bottom perspective view of the rigid roofing substrate of FIG. 9;

FIG. 11 is a schematic cross-sectional view of a rigid photovoltaic roofing element according to another embodiment of the invention;

FIG. 12 is a schematic cross-sectional view of a rigid photovoltaic roofing element according to one embodiment of the invention disposed on a roof deck;

FIG. 13 is a schematic cross-sectional view of a rigid photovoltaic roofing element according to another embodiment of the invention disposed on a roof deck;

FIG. 14 is a schematic cross-sectional view of adjacent rigid photovoltaic roofing elements disposed on a roof deck according to one embodiment of the invention; and

FIG. 15 is a schematic cross-sectional view of adjacent rigid photovoltaic roofing elements disposed on a roof deck according to another embodiment of the invention.

### DETAILED DESCRIPTION OF THE INVENTION

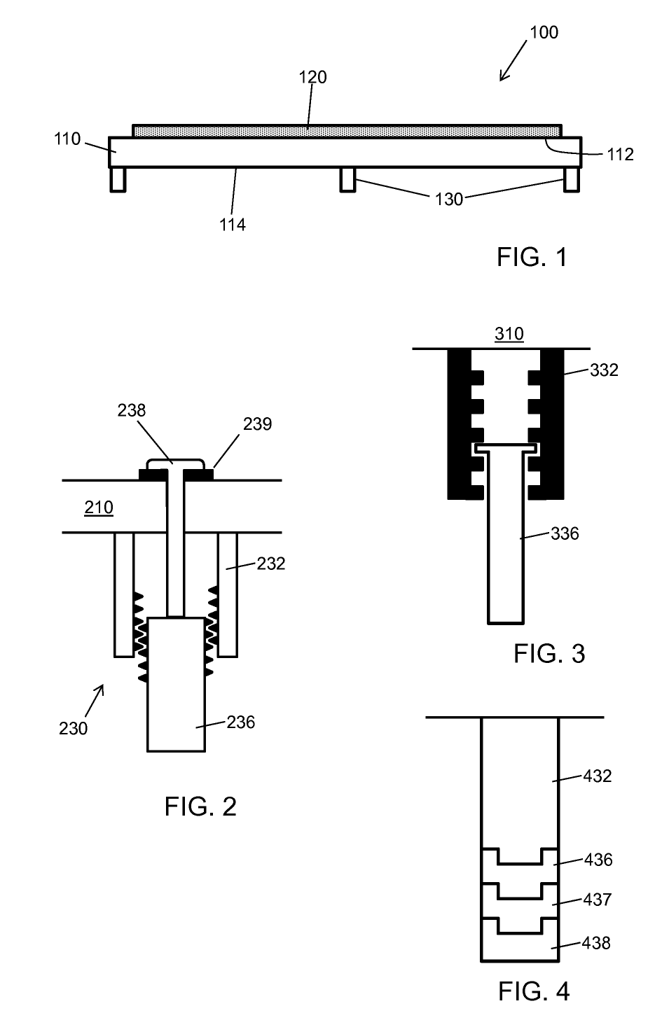

One aspect of the invention is a rigid photovoltaic roofing element. An example according to one embodiment of the invention is shown in schematic cross-sectional view in FIG. 1. Rigid photovoltaic roofing element 100 includes a rigid roofing substrate 110 having a top face 112 and a bottom face 114. Disposed on the top face of the rigid roofing substrate is a photovoltaic element 120. Extending from the bottom face of the rigid roofing substrate are one or more adjustable leveling elements 130. While the one or more adjustable leveling elements extend from the bottom face of the rigid roofing substrate, they can interface with the rigid roofing substrate at any appropriate location (e.g., the bottom face of the rigid roofing substrate, or a side edge of the rigid roofing substrate).

A “rigid photovoltaic roofing element,” as used in the present disclosure, can provide both photovoltaic functionality and environmental protection to the roof. The rigid photovoltaic roofing element can be disposed directly on a roof deck, i.e., without shingles, tiles, panels, or other standard top-level roof coverings disposed underneath. As the person of skill in the art would understand, there can be one or more layers of material (e.g. underlayment or other waterproofing or fire-resistant membrane as generally required by local building codes), between the roof deck and the rigid photovoltaic roofing elements. The rigid photovoltaic roofing elements can be disposed on a roof together with one or more standard roofing elements, for example to provide weather protection at the edges of the roof, or in areas not suitable for photovoltaic power generation. In some embodiments, non-photovoltaically-active roofing elements are complementary in appearance or visual aesthetic to the rigid photovoltaic roofing elements. Standard roofing elements can be interleaved at the edges of the photovoltaic arrays described herein. In certain embodiments, the photovoltaic roofing elements are simply disposed on top of an already-installed array of standard roofing elements (e.g., an already-shingled roof), for example, with substantially no space therebetween.

In certain embodiments, as described in more detail below, the adjustable leveling elements can be adjusted to support the rigid photovoltaic roofing element on an uneven surface; or to level the rigid photovoltaic roofing element with respect to other photovoltaic roofing elements disposed on an uneven surface. The adjustable leveling elements need not be particularly long; for example, in certain embodiments, the adjustable leveling element can be adjusted to extend from the bottom face of the rigid roofing substrate by at least about ⅛″, at least about ¼″, or even at least about ½″. In certain embodiments, the adjustable leveling elements are adjustable to a maximum distance from the bottom face of the rigid roofing substrate of about 2″, of about 1.5″, or of about 1″.

In certain embodiments, the one or more adjustable leveling elements can be reversibly adjusted. In other embodiments, the one or more adjustable leveling elements are only irreversibly adjustable (e.g., irreversibly shortenable).

In certain embodiments, the one or more adjustable leveling elements include one or more adjustable legs extending from the bottom surface of the rigid roofing substrate. The legs can take a variety of shapes. For example, in certain embodiments, the legs have a cross-sectional shape selected from round, rectangular, triangular, cruciform or other polygonal shapes. The legs can be hollow or solid, or a combination thereof. The legs can be formed with any desirable aspect ratio. For example, in some embodiments, the legs are taller than they are wide; in other embodiments; the legs are shorter than at least one of the dimensions perpendicular to their height. In certain embodiments, a rigid roofing substrate includes different kinds of legs, for example, wide square-shaped legs at the corners of the rigid roofing substrate, and narrower tube-shaped legs in other parts of the rigid roofing substrate.

In certain embodiments, the one or more adjustable leveling elements include a plurality of interfaced pieces. For example, in one embodiment, an adjustable leveling element includes a first piece that interfaces with the rigid roofing substrate; and a second piece that interfaces with the first piece. In certain embodiments, the interface between the two pieces can be adjustable to provide an adjustment in height. In other embodiments, the second piece can be removed altogether to provide an adjustment. Similarly, the adjustable leveling elements can further include a third piece that interfaces with the second piece. The interface between the second piece and the third piece can be adjustable to provide an adjustment in height. In other embodiments, the third piece can be removed altogether to provide an adjustment.

One embodiment of an adjustable leveling element is shown in partial cross-sectional schematic view in FIG. 2. Adjusting leveling element 230 includes a first segment 232 interfacing with the rigid roofing substrate 210 and a second segment 236 interfacing with the first. In this embodiment, the first segment is threadedly engaged with the second segment. The first segment has threads on its inner surface; and the second segment has mating threads on its outer surface. The second segment can be screwed into or out of the first to provide an adjustment in height. Of course, in other embodiments, the first segment can screw into the second segment. In certain embodiments, the adjustable leveling element can further include a third segment threadedly engaged with the second segment. In the embodiment of FIG. 2, the second segment has attached thereto a screwable extension 238 that protrudes through the rigid roofing substrate 210, which allows the installer to adjust the height from the top face of the rigid photovoltaic roofing element. The screwable extension can be configured to be movable vertically with respect to the second segment, but not annularly, such that the screwable extension remains in substantially the same vertical position. In this embodiment, a gasket 239 seals the hole formed through the rigid roofing substrate; in other embodiments, a cap or a layer of sealant may cover the screwable extension to prevent water ingress.

Another embodiment of an adjustable leveling element is shown in cross-sectional schematic view in FIG. 3. In this embodiment, the second element engages the first segment via a multi-position snap lock, i.e., the second segment snaps together with the first segment in a plurality of positions, each providing a different height to the adjustable leveling element. In FIG. 3, the adjustable leveling element includes a first segment 332 interfacing with the rigid roofing substrate 310 and a second segment 336 interfacing with the first. On the inner surface of the first segment and on the outer surface of the second segment are snap-lock features that allow the second feature to be disposed within the first at a plurality of different positions, thus providing a set of different possible heights for the adjustable leveling element. Of course, in other embodiments, the first segment can snap into the second segment. In certain embodiments, the adjustable leveling element can further include a third engaged with the second segment via a multi-position snap lock.

In another embodiment, a downward-facing surface of the first element sits upon an upward-facing surface of the second element. One example of such an embodiment is shown in cross-sectional schematic view in FIG. 4. In FIG. 4, first segment 432 has a downward-facing surface that sits on an upward-facing surface of second segment 436. The embodiment of FIG. 4 also includes third segment 437 and fourth segment 438. In such embodiments, segments can be added or removed to provide a desired height to the adjustable leveling element. In certain embodiments, the segments can be affixed to one another with adhesive or tape; in other embodiments, the adjustable leveling elements are simply held together by friction (e.g., sufficient friction to allow them to be installed; when disposed on the roof, pressure will keep them from moving). Accordingly, in certain embodiments, adjustment can be formed by adding or subtracting segments from the adjustable leveling element.

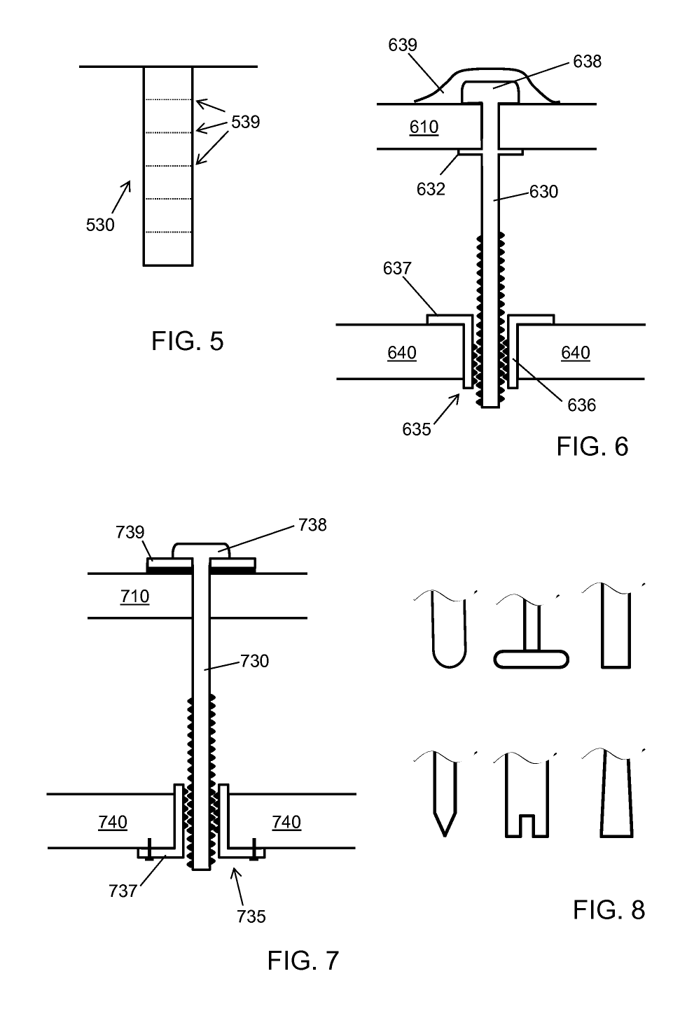

In certain embodiments, the one or more adjustable elements are legs configured to be cut to change their lengths. An example is shown in cross-sectional schematic view in FIG. 5. In this embodiment, adjustable leveling element 530 is formed from a cuttable material such as plastic. The adjustable leveling element to be cut to provide a desired height. In certain embodiments, and as shown in FIG. 5, the cuttable legs are marked at fixed increments (markings denoted with reference numeral 539) to provide the user visual guidance as to where to cut. The markings can be, for example, horizontal or diagonal rings, either raised or recessed into the surface of the leg. The markings can be labeled with distances. Of course, in other embodiments, the leg includes no such markings. The cuttable element can be formed to be long enough to provide support for a relatively large deviation in the plane of the roof (e.g., longer than any non-adjustable legs extending from the bottom surface of the rigid roofing substrate, for example, by at least ¼″, at least ½″, or even at least 1″).

In certain embodiments, the one or more adjustable leveling elements include threads that engage threads on a threaded element that engages the roof deck. For example, one embodiment is shown in cross-sectional schematic view in FIG. 6. In this embodiment, the adjustable leveling element 630 is a bolt that has threads that engage the threads of threaded element 635 that engages the roof deck 640. In this embodiment, the threaded element 635 includes threads configured to mate with the threads of the adjustable leveling element; and a feature, such as a flange, that engages the roof deck (e.g., to hold the threaded element against a top or bottom surface of the roof deck). The threaded element can be cylindrically symmetrical, or can have a variety of other shapes as the person of skill in the art will appreciate. The threaded element can, for example, be affixed to the roof deck so as to prevent it from rotating (e.g., when the adjustable leveling element is screwed into or out of it). In other embodiments, the shape of the threaded element can be such that it does not freely rotate. In certain embodiments, and as shown in FIG. 6, the roof deck has a hole formed therethrough through which the adjustable leveling element can be disposed (i.e., when it is screwed in sufficiently far).

In the embodiment of FIG. 6, the threaded element 635 has a cylindrical portion 636 that includes the threads (here, disposed in the hole in the roof deck), and a flange 637 engaging the roof deck (here, sitting on the top surface thereof). Accordingly, when the adjustable leveling element pushes against the cylindrical portion of the threaded element 635, the flange 637 holds the threaded element (and therefore the bolt) in position against the roof. This configuration can be used, for example, to provide the photovoltaic roofing element an offset distance from the roof deck that is greater than the offset distance that would exist without the adjustable leveling element (i.e., it can push the rigid roofing substrate 610 of the photovoltaic roofing element farther from the roof deck, even flexing it a little in some embodiments). As described above with reference to FIG. 2, the head 638 of the bolt (i.e., a “screwable extension”) can be turned, thereby screwing the adjustable leveling element into or out of the threaded element to provide the desired offset distance. In this embodiment, the adjustable leveling element also includes a flange 632 that engages the bottom surface of the rigid roofing substrate 610, so that it is held at the desired offset distance from the roof deck. Moreover, in this embodiment, the head of the bolt is covered by a sealant 639 to prevent water ingress. Thus, the desired offset distance can be set by turning the head of the bolt; then the head can be potted in with sealant.

Another embodiment is shown in cross-sectional schematic view in FIG. 7. In the embodiment of FIG. 7, the flange 737 of the threaded element 735 engages the bottom surface of the roof deck 740. Accordingly, it can be installed from underneath the roof deck. In this embodiment, when the adjustable leveling element 730 pulls against the cylindrical portion of the threaded element 735, the flange 737 holds the threaded element (and therefore the bolt) in position against the roof. In this embodiment, the flange is affixed to the roof (here, by nails). This configuration can be used, for example, to provide the photovoltaic roofing element an offset distance from the roof deck that is less than the offset distance that would exist without the adjustable leveling element (i.e., it can pull the rigid roofing substrate 710 of the photovoltaic roofing element closer to the roof deck, even flexing it a little in some embodiments). As described above with reference to FIG. 2, the head 738 of the bolt can be turned thereby screwing the adjustable leveling element into or out of the threaded element to provide the desired offset distance. In this embodiment, a washer 739 (or a similar element with larger surface area between the head of the bolt and the roofing substrate) can be used to provide a more spread-out force on the roofing substrate.

The bottom end of the adjustable leveling element (i.e., the end that sits on the roof) can take any number of shapes. A variety of suitable shapes are shown in cross-sectional view in FIG. 8. In other embodiments, the bottom end of the adjustable leveling element includes two or more contact points, for example, an open U-shape as shown in the bottom center example of FIG. 8, or a tripod or quadrapod shape.

Of course, as the person of skill in the art will appreciate, the adjustable leveling elements can take forms other than those explicitly described herein.

The one or more adjustable leveling elements can interface with the rigid roofing substrate in a variety of ways. For example, in certain embodiments, the adjustable leveling element is integrally formed with the rigid roofing substrate. For example, when the adjustable leveling element is cuttable as described above with respect to FIG. 5, it can be formed as part of the rigid roofing substrate. Similarly, when the adjustable leveling element includes a plurality of separate segments (e.g., as described above with respect to FIGS. 2-4), the first segment can be formed as part of the rigid roofing substrate. Such configurations can be constructed, for example, using plastic molding processes.

In another embodiment, the adjustable leveling element is affixed to the rigid roofing substrate. For example, the adjustable leveling element can be affixed with a fastener, such as a screw, a rivet, a bolt, a clip, or a brad. In other embodiments, the adjustable leveling element is affixed to the rigid roofing substrate with an adhesive.

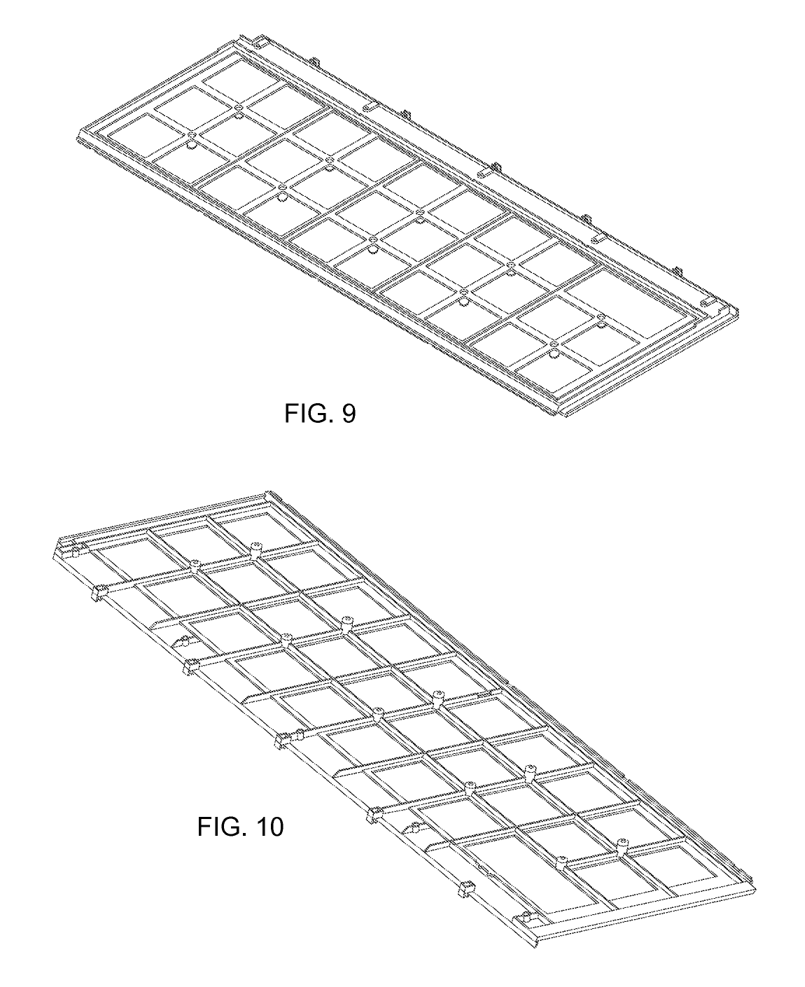

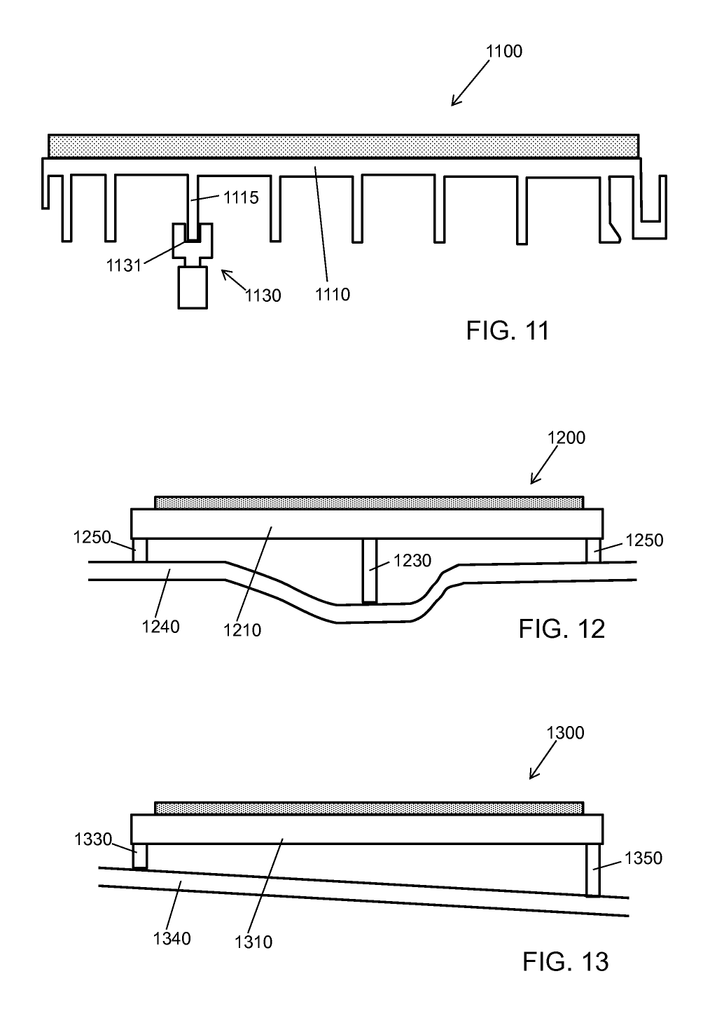

In certain embodiments, the adjustable leveling element includes a feature adapted to mate with a corresponding feature on the bottom face of the rigid roofing substrate. For example, in certain embodiments, the rigid roofing substrate has ribs formed on its bottom surface. The ribs can, for example, provide support to the structure of the rigid roofing substrate. One example of such a rigid roofing substrate is shown in top perspective view in FIG. 9 and in bottom perspective view in FIG. 10; such rigid roofing substrates are described, for example, in U.S. patent application Ser. No. 13/326,094, which is hereby incorporated herein by reference in its entirety. FIG. 11 is a cross-sectional view of a rigid photovoltaic element 1100 with an adjustable leveling element 1130, with a slot 1131 which engages a rib 1115 of the rigid roofing substrate 1110. In other embodiments, a tongue-in-groove or a press-fit interface is used. In certain embodiments, the mating features positively interlock, so as to snap together.

In certain embodiments, an adjustable leveling element is disposed in an interior region of the rigid roofing substrate. One example is shown in schematic cross-sectional view in FIG. 12. Rigid photovoltaic roofing element 1200 is disposed on a roof surface 1240 that is substantially non planar, in this example with a dip underneath the interior region of the rigid roofing substrate 1210 (i.e., substantially away from the edges of the rigid roofing substrate). In the embodiment of FIG. 12, the rigid photovoltaic roofing element includes non-adjustable legs 1250 at the edges of the rigid roofing substrate. Adjustable leg 1230 is shown as being extended to support the central portion of the rigid photovoltaic roofing element over the dip in the roof surface. Accordingly, if the photovoltaic roofing element is stepped on, the adjustable leg can support the weight in its central portion.

In other embodiments, an adjustable leveling element is disposed along a side edge of the rigid roofing substrate. One example is shown in schematic cross-sectional view in FIG. 13. Rigid photovoltaic roofing element 1300 is disposed on a roof surface 1340 that is substantially non planar, here, slanting from right to left. The rigid roofing substrate 1310 includes a non-adjustable leg 1350 on its right edge; and an adjustable leg 1330 on its left end. Here, the adjustable leg is shortened so as to provide the desired slant to the rigid photovoltaic roofing element.

In certain embodiments, as described above, the rigid roofing substrate includes one or more non-adjustable legs. The non-adjustable legs can be formed in a variety of shapes, as described above with respect to adjustable legs. In certain embodiments, when the adjustable leveling element is provided together with one or more non-adjustable legs, it can be adjustable to be long enough to provide support for a relatively large deviation in the plane of the roof (e.g., longer than any non-adjustable legs extending from the bottom surface of the rigid roofing substrate, for example, by at least ¼″, at least ½″, or even at least 1″).

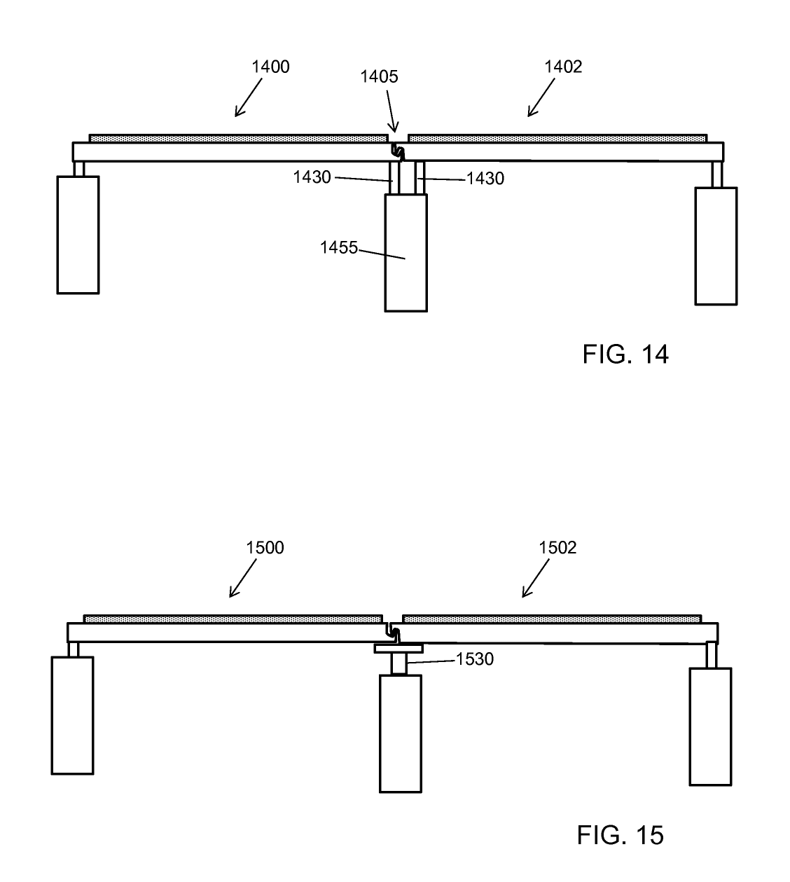

In certain embodiments, the adjustable legs can be used to level adjacent photovoltaic roofing elements relative to one another. An example of such an embodiment is shown in cross-sectional schematic view in FIG. 14. In this embodiment, the rigid photovoltaic roofing elements 1400, 1402 are disposed directly on rafters 1455. The adjustable leveling elements 1430 level the rigid photovoltaic roofing elements with respect to one another, so that their interlocking edges (denoted generally by reference number 1405) interlock properly with one another. Thus, the use of the adjustable leveling elements can help prevent water intrusion as a result of improper mating of adjacent rigid photovoltaic roofing elements.

In certain embodiments, a single adjustable leveling element is used to support the rigid roofing substrates of two adjacent rigid photovoltaic roofing elements. An example of such an embodiment is shown in cross-sectional schematic view in FIG. 15. A single adjustable leveling element 1530 supports the rigid roofing substrates of rigid photovoltaic roofing elements 1500 and 1502.

A wide variety of rigid roofing substrates can be used in practicing various aspects of the present invention. For example, in one aspect, the rigid roofing substrate is a frame structure as described in U.S. patent application Ser. No. 13/326,094, which is hereby incorporated herein by reference in its entirety. Any appropriate combination of the embodiments described of that disclosure with the embodiments described in the present disclosure is specifically envisioned. In another aspect, the rigid roofing substrate is as described in U.S. Patent Application Publication no. 2009/0000222, which is hereby incorporated herein by reference in its entirety. Any appropriate combination of the embodiments described of that disclosure with the embodiments described in the present disclosure is specifically envisioned.

In certain embodiments, the rigid roofing substrate includes sidelap portions disposed at its lateral edges and having geometries adapted to interlock with adjacent rigid photovoltaic roofing elements to provide water drainage channels. For example, in one embodiment, the sidelap portion at one lateral edge has an upward-facing water drainage channel; and the sidelap portion at the other lateral edge has a downward-facing flange that fits into the water drainage channel of an adjacent (e.g., identical) photovoltaic roofing element. This configuration is shown, for example, in FIGS. 11 and 14. This configuration is preferred, as it allows a single type of rigid photovoltaic roofing element to be used in an installation. Of course in other embodiments, a single rigid photovoltaic element can have two upward-facing water drainage channels, or two downward-facing flanges in its sidelap portions; as long as such rigid photovoltaic roofing elements are properly mated with the corresponding features on adjacent rigid photovoltaic roofing elements, they can be used to construct a water-tight photovoltaic roofing system. When installed, any water that moves over the lateral edges of the photovoltaic roofing element will be delivered into the water drainage channel, where it can be delivered down the roof. In certain embodiments, the water drainage channel is open at the bottom edge of the frame structure, such that water can flow out of it and down over the next course of photovoltaic roofing elements.

Rigid roofing substrates can be made from a variety of materials. For example, plastic materials such as polycarbonate; metal materials such as aluminum; wood; or ceramic materials; or composite materials. The adjustable leveling elements can be made from a variety of materials, such as metallic materials; polymeric materials such as rubber, neoprene, nylon, polypropylene, polyethylene and polycarbonate; and composite materials. Substrates and adjustable leveling elements can be coated, for example, with rubberized or elastomeric treatments.

Photovoltaic elements suitable for use in the present invention generally comprise one or more interconnected photovoltaic cells. The photovoltaic cells can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide or CIGS. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Thin-film amorphous silicon materials can also be used, which can be provided in flexible forms. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of photovoltaic elements for use in the present invention. In one embodiment of the invention, the photovoltaic element includes a monocrystalline silicon photovoltaic cell or a polycrystalline silicon photovoltaic cell.

The photovoltaic element can optionally comprise various other materials and features, such as a backing substrate (e.g., plastic or metal sheet); a protective covering (e.g., a polymeric film or glass sheet); a granule-coated layer as described in U.S. Patent Application Publication no. 2008/0271773, which is hereby incorporated herein by reference its entirety; an opaque, semi-opaque, colored or patterned cover element as described in U.S. Patent Application Publication no. 2009/0000221, which is hereby incorporated herein by reference in its entirety; mounting structures (e.g., clips, holes, or tabs); and one or more optionally connectorized electrical cables for electrically interconnecting the photovoltaic cell(s) of the encapsulated photovoltaic element with an electrical system. The person of skill in the art will recognize that photovoltaic elements for use in the present invention can take many forms, and include many materials and features not specifically mentioned here.

The photovoltaic elements can be encapsulated photovoltaic elements, in which photovoltaic cells are encapsulated between various layers of material. For example, encapsulated photovoltaic element can include a top layer material at its top surface, and a bottom layer material at its bottom surface. The top layer material can, for example, provide environmental protection to the underlying photovoltaic cells, and any other underlying layers. Examples of suitable materials for the top layer material include fluoropolymers, for example ETFE (e.g., NORTON® ETFE films available from Saint-Gobain), PFE, FEP (e.g., NORTON® FEP films available from Saint-Gobain), PCTFE or PVDF. The top layer material can alternatively be, for example, a glass sheet, or a non-fluorinated polymeric material. The bottom layer material can be, for example, a fluoropolymer, for example ETFE, PFE, FEP, PVDF or PVF (“TEDLAR”). The bottom layer material can alternatively be, for example, a polymeric material (e.g., polyester such as PET, or polyolefin such as polyethylene); or a metallic material (e.g., stainless steel or aluminum sheet).

As the person of skill in the art will appreciate, an encapsulated photovoltaic element can include other layers interspersed between the top layer material and the bottom layer material. For example, an encapsulated photovoltaic element can include structural elements (e.g., a reinforcing layer of glass fiber, microspheres, metal or polymer fibers, or a rigid film); adhesive layers (e.g., EVA to adhere other layers together); mounting structures (e.g., clips, holes, or tabs); and one or more optionally connectorized electrical cables for electrically interconnecting the photovoltaic cell(s) of the encapsulated photovoltaic element with an electrical system.

The photovoltaic element can include at least one antireflection coating, for example as the top layer material in an encapsulated photovoltaic element, or disposed between the top layer material and the photovoltaic cells.

Suitable photovoltaic elements and/or photovoltaic cells can be obtained, for example, from China Electric Equipment Group of Nanjing, China, as well as from several domestic suppliers such as Uni-Solar, Sharp, Shell Solar, BP Solar, USFC, FirstSolar, General Electric, Schott Solar, Evergreen Solar and Global Solar. Thin film-based photovoltaic cells can be especially suitable due to their durability, low heat generation, and off-axis energy collection capability. The person of skill in the art can fabricate encapsulated photovoltaic elements using techniques such as lamination or autoclave processes. Encapsulated photovoltaic elements can be made, for example, using methods disclosed in U.S. Pat. No. 5,273,608, which is hereby incorporated herein by reference. Commercially available photovoltaic devices can be manipulated (e.g., by backing with a substrate) in order to provide the photovoltaic elements used in the present invention.

Another aspect of the invention is a photovoltaic roofing system including a plurality of rigid photovoltaic roofing elements as described herein, arranged in an array and disposed on a roof. The rigid photovoltaic roofing elements can, for example, be disposed upon directly upon a roof deck, optionally with one or more layers of roofing underlayment therebetween. In other embodiments, the rigid photovoltaic roofing elements can be disposed on the rafters of a roof. As the person of skill in the art will appreciate, the rigid photovoltaic roofing elements can be affixed to the roof in a variety of ways. For example, the rigid photovoltaic roofing elements can be nailed or screwed to the roof in an overlapping fashion, as is conventional in the roofing arts.

In certain embodiments, the adjustable leveling features of two adjacent rigid photovoltaic roofing elements are adjusted to different positions; and the two adjacent rigid photovoltaic roofing elements are substantially coplanar. The photovoltaic roofing systems described herein can be utilized with many different building structures, including residential, commercial and industrial building structures.

Another aspect of the invention is a kit for the installation of a photovoltaic roofing system. The kit includes a rigid photovoltaic roofing element as described herein. The kit further includes one or more adjustable leveling elements as described herein, configured to be interface with the rigid roofing substrate so as to extend from its bottom face. For example, in one embodiment, the adjustable leveling elements are configured to be affixed to the bottom face of the rigid roofing substrate. In certain embodiments, the adjustable leveling elements include a feature adapted to mate with a corresponding feature on the bottom face of the rigid roofing substrate, for example, via a positive interlock. The kit can in certain embodiments include other elements, for example, flashings and cant strips, for example as described in U.S. patent application Ser. No. 13/326,094.

Another aspect of the invention is a method for installing a photovoltaic roofing system on a roof. The method includes disposing a rigid photovoltaic roofing element as described herein on a roof (e.g., on a roof deck or on one or more roof structural elements such as rafters). The method also includes disposing one or more adjustable leveling elements extending from the bottom face of the rigid roofing substrate of the rigid photovoltaic roofing element to the roof. For example, the one or more adjustable leveling elements can be provided together with the rigid photovoltaic roofing element. In other embodiments, the one or more adjustable leveling elements can be provided as separate pieces, for example, in regions where leveling is required. The method further includes adjusting one or more of the adjustable leveling elements. For example, the adjustment can be performed to make a rigid photovoltaic roofing element substantially coplanar with the overall plane of a roof, even where the local roof surface includes substantial deviations from the overall plane of a roof. In certain embodiments, the adjustment can be performed to support a portion of the rigid photovoltaic roofing element over a local dip in the roof surface. In certain embodiments, the adjustment can be performed to make two adjacent rigid photovoltaic roofing elements substantially coplanar. The method can also include affixing the rigid photovoltaic roofing element to the roof, for example, after performing an adjustment as described above. In certain embodiments, the method described above the adjustment is performed to align a first lateral edge of the rigid photovoltaic roofing element with a second lateral edge of an adjacent rigid photovoltaic roofing element.

The foregoing description of embodiments of the present invention has been presented for the purposes of illustration and description. It is not intended to be exhaustive or to limit the invention to the precise forms disclosed. As the person of skill in the art will recognize, many modifications and variations are possible in light of the above teaching. It will be apparent to those skilled in the art that various modifications and variations can be made to the present invention without departing from the scope of the invention. Thus, it is intended that the present invention cover the modifications and variations of this invention provided they come within the scope of the claims and their equivalents.

What is claimed is:

1. A rigid photovoltaic roofing element comprising:
a rigid roofing substrate having a top face and a bottom face; and
a photovoltaic element disposed on the top face of the rigid roofing substrate,
wherein the rigid roofing substrate includes one or more adjustable leveling elements extending from the bottom face thereof.

2. The rigid photovoltaic roofing element according to claim 1, wherein the one or more adjustable leveling elements comprise one or more legs extending from the bottom surface of the rigid roofing substrate.

3. The rigid photovoltaic roofing element according to claim 1, wherein each adjustable leveling element includes a first segment interfacing with the rigid roofing substrate, and a second segment interfacing with the first segment.

4. The rigid photovoltaic roofing element according to claim 3, wherein the second element is threadedly engaged with the first segment.

5. The rigid photovoltaic roofing element according to claim 3, wherein the second segment engages the first segment via a multi-position snap lock.

6. The rigid photovoltaic roofing element according to claim 3, wherein a downward-facing surface of the first segment sits upon an upward-facing surface of the second segment.

7. The rigid photovoltaic roofing element according to claim 1, wherein the one or more adjustable leveling elements include threads that engage threads on a threaded element that engages a roof deck upon which the rigid photovoltaic roofing element is disposed.

8. The rigid photovoltaic roofing element according to claim 1, wherein the one or more adjustable leveling elements comprise one or more cuttable elements.

9. The rigid photovoltaic roofing element according to claim 8, wherein the cuttable elements include markings at fixed increments.

10. The rigid photovoltaic roofing element according to claim 1, wherein the one or more adjustable leveling elements are integrally formed with the rigid roofing substrate.

11. The rigid photovoltaic roofing element according to claim 1, wherein the one or more adjustable leveling elements are affixed to the rigid roofing substrate.

12. The rigid photovoltaic roofing element according to claim 1, wherein the adjustable leveling element includes a feature adapted to mate with a corresponding feature on the bottom face of the rigid roofing substrate.

13. The rigid photovoltaic roofing element according to claim 1, wherein a portion of the roof surface upon which the rigid photovoltaic roofing element is disposed is substantially nonplanar.

14. The rigid photovoltaic roofing element according to claim 1, wherein the adjustable leveling elements can be adjusted to extend from the bottom face of the rigid roofing substrate by at least about ½″.

15. The rigid photovoltaic roofing element according to claim 1, wherein the adjustable leveling elements are adjustable to a maximum distance from the bottom face of the rigid roofing substrate of about 2″.

16. A photovoltaic roofing system comprising a plurality of rigid photovoltaic roofing elements according to claim 1, arranged in an array and disposed on a roof

17. A photovoltaic roofing system according to claim 16, wherein a single adjustable leveling element is used to support the rigid roofing substrates of two adjacent rigid photovoltaic roofing elements.

18. A photovoltaic roofing system according to claim 16, wherein the adjustable leveling elements of two adjacent rigid photovoltaic roofing elements are adjusted to different positions; and the two adjacent rigid photovoltaic roofing elements are substantially coplanar.

19. A kit for the installation of a photovoltaic roofing system, the kit comprising:
a rigid photovoltaic roofing element comprising
a rigid roofing substrate having a top face and a bottom face, and
a photovoltaic element disposed on the top face of the rigid roofing substrate; and
one or more adjustable leveling elements configured to interface with the bottom face of the rigid roofing substrate.

20. A method for the installation of a photovoltaic roofing system, the method comprising
disposing on a roof a rigid photovoltaic roofing element comprising
a rigid roofing substrate having a top face and a bottom face, and
a photovoltaic element disposed on the top face of the rigid roofing substrate; and
disposing one or more adjustable leveling elements extending from the bottom face of the rigid roofing substrate of the rigid photovoltaic roofing element to the roof; and then
adjusting one or more of the adjustable leveling elements.

21. The method according to claim 20, wherein the adjustment is performed to make the rigid photovoltaic roofing element substantially coplanar with the overall plane of the roof.

22. The method according to claim 20, wherein the adjustment is performed to make the rigid photovoltaic roofing element substantially coplanar with an adjacent rigid photovoltaic roofing element.

23. The method according to claim 20, wherein the adjustment is performed to align a first lateral edge of the rigid photovoltaic roofing element with a second lateral edge of an adjacent rigid photovoltaic roofing element.
